(19) United States
(12) Patent Application Publication
(10) Pub. No.: US 2008/0210963 A1
(43) Pub. Date: Sep. 4, 2008

(54) LIGHT EMITTING DIODE PACKAGE STRUCTURE AND METHOD OF MAKING THE SAME

(76) Inventors: Hung-Yi Lin, Tao-Yuan Hsien (TW); Hong-Da Chang, Tai-Chung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/841,005

(22) Filed: Aug. 20, 2007

(30) Foreign Application Priority Data
Mar. 1, 2007 (TW) 096106993

(51) Int. Cl. H01L 33/00; H01L 21/00

(52) U.S. Cl. 257/98; 438/28; 257/E33.001; 257/E21.001

(57) ABSTRACT

A light emitting diode package structure has a silicon substrate, a plurality of cup-structures on the silicon substrate, a plurality of conductive patterns disposed on the silicon substrate, one of a plurality of light emitting diodes respectively disposed on each cup-structure and a plurality of wires electrically connected to the light emitting diodes and the conductive patterns. The light emitting diodes are electrically connected in series through the conductive wires and the conductive patterns.

### BACKGROUND OF THE INVENTION

1. Field of the Invention

The present invention relates to a light emitting diode package structure having a silicon substrate, and more particularly, to a light emitting diode having high operating voltage and a method of making the same by using interconnection.

2. Description of the Prior Art

Since the light emitting diode has advantages of a long lifetime, a small size, a high resistance to shock, a low heat emission, and a low consumption of electrical power, the light emitting diode is widely applied as a pilot lamp or a light source for various household appliances and instruments. Additionally, the LED has been developed toward producing colorful lights and high brightness in recent years, so that the LED is further applied in many kinds of movable or large-sized electronic products ranging from being a back light source of a display, lamps, traffic signals and outside colorful signboards to becoming a stream of illumination light sources with low power consumption and low contamination characteristics in the future.

Please refer to FIG. 1. FIG. 1 is a schematic diagram illustrating a light emitting diode package structure according to the prior art. As shown in FIG. 1, the light emitting diode package structure includes a light emitting diode 12, a mount lead 14 and an inner lead 16, wherein the mount lead 14 includes a cup-structure, and the light emitting diode 12 is disposed in the cup-structure of the mount lead 14. In addition, two electrodes of the light emitting diode 12 are respectively electrically connected to the mount lead 14 and the inner lead 16 through wires 18. The cup-structure is filled with a sealing material 20, and the sealing material 20 covers the top of the mount lead 14 and the inner lead 16.

The operating voltage of the light emitting diode package structure is about 3 volts, less than general voltage standard, such as household standard (110 volts), automotive standard (12 volts) or industrial standard (220 volts), so the light emitting diode package structure has to be further connected to a transformer or general dry cell with small voltage to work. Taking the automotive standard that is 12 volts as an example, one light emitting diode cannot be directly used with the automotive standard. In order to operate in the voltage standard, a plurality of the packaged light emitting diodes have to be connected in series so that the operating voltage of the light emitting diode package structure can reach 12 volts. However, after packaging in series, the size of the light emitting diode package structure will be large, and the light pattern of the light emitting diode package structure will have many dark regions in the gaps between the light emitting diodes. Therefore, to improve the light emitting diode that cannot directly operate in a high voltage standard and to reduce the package size are important subjects.

### SUMMARY OF THE INVENTION

It is therefore an object to provide a light emitting diode package structure having a high operating voltage and a method making the same so as to be used in a general voltage standard.

According to a preferred embodiment of the present invention, a light emitting diode package structure is provided. The light emitting diode package structure comprises a silicon substrate, a plurality of cup-structures disposed on a top surface of the silicon substrate, a plurality of conductive patterns disposed on the top surface of the silicon substrate, one of a plurality of light emitting diodes respectively disposed in each cup-structure and a plurality of wires electrically connecting the light emitting diodes to the conductive patterns. The light emitting diodes are electrically connected in series through the wires and the conductive patterns.

According to a preferred embodiment of the present invention, a method of making a light emitting diode package structure having a silicon substrate is provided. First, a silicon substrate having a plurality of cup-structures is provided. Next, a plurality of conductive patterns is formed on the silicon substrate, and one of a plurality of light emitting diodes is respectively disposed in each cup-structure. The light emitting diodes are electrically connected to the conductive patterns through a plurality of wires, and the light emitting diodes are electrically connected in series through the wires and the conductive patterns.

The present invention uses a semiconductor process to fabricate a silicon substrate having cup-structures and conductive patterns. Combined with a light emitting diode packaging process, a light emitting diode package structure including a plurality of light emitting diodes are formed. The present invention also provides a light emitting diode package structure corresponding to a specific high voltage specification.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a light emitting diode package structure according to the prior art.

FIG. 2 is a top view illustrating a light emitting diode package structure according to a preferred embodiment of the present invention.

FIG. 3 is a cross-sectional diagram illustrating a light emitting diode package structure according to a preferred embodiment of the present invention.

FIG. 4 is a top view illustrating a light emitting diode package structure according to another preferred embodiment of the present invention.

FIG. 5 to FIG. 7 are schematic diagrams illustrating a method of making a light emitting diode package structure having a silicon substrate according to an embodiment of the present invention.

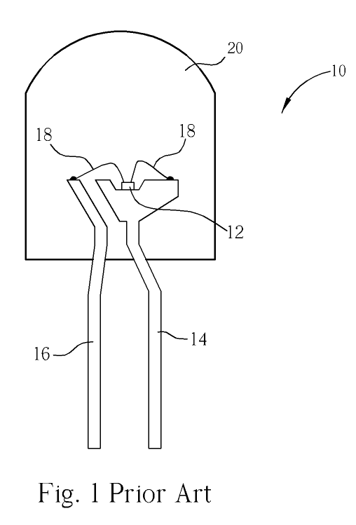

### DETAILED DESCRIPTION

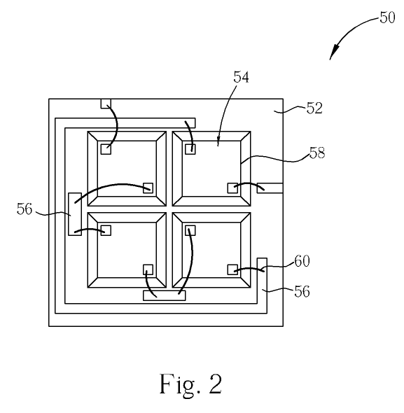

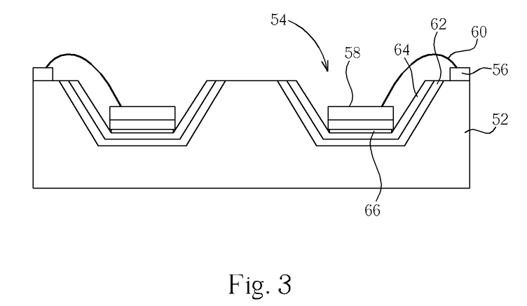

Please refer to FIG. 2 and FIG. 3. FIG. 2 is a top view illustrating a light emitting diode package structure according to a preferred embodiment of the present invention. FIG. 3 is a cross-sectional diagram illustrating a light emitting diode package structure according to a preferred embodiment of the present invention. As shown in FIG. 2, the light emitting diode package structure 50 includes a silicon substrate 52, four cup-structures 54, a plurality of conductive pattern 56, four light emitting diode 58 and a plurality of wires 60. The cup-structures 54 are disposed on the silicon substrate 52, and arranged in a rectangular array. Each cup-structure 54 has inclined sidewalls, and the distance between the edges of adjacent cup-structures 54 is substantially less than 10 μm. The inclined angle of the sidewalls and the distance between the edges of the adjacent cup-structure 54 can be modified according to the requirements. The conductive patterns 56 are disposed on the silicon substrate 52 surrounding the cup-structures 54 and can be electrically connected the external driving circuits or driving voltage (not shown in figure). The light emitting diodes 58 is respectively disposed in each cup-structure 54. The wires 60 are electrically connecting the light emitting diodes 58 and the conductive patterns 56 so that the external driving voltage can drive the light emitting diodes 58 through the conductive patterns 56 and the wires 60. It should be noted that the light emitting diodes are electrically connected in series through the wires 60 and the conductive patterns 56.

In addition, as shown in FIG. 3, the light emitting diode package structure 50 further includes a reflective layer 62, a transparent insulating layer 64 and four metal bumps 66. The reflective layer 62 and the transparent insulating layer 64 are disposed on the silicon substrate 52 in the cup-structures 54 from bottom to top in turn, and one metal bump 66 is respectively disposed on the transparent insulating layer 64 in each cup-structure 54. The reflective layer 62 is composed of metal or optical films and used to reflect the light emitted from the side surface of the light emitting diode 58. Besides, the silicon substrate 52 includes polycrystalline silicon, amorphous silicon or monocrystalline, and the silicon substrate 52 can be square silicon chip or circular silicon chip that includes finished integrated circuits or passive devices (not shown in figure). The finished integrated circuits or passive devices and the light emitting diodes 58 can form a lighting system. The silicon substrate also has good thermal conductivity, so the light emitting diodes 58 bonded to the silicon substrate 52 can have a good thermal dissipation environment when the light emitting diode 58 is lit.

In this embodiment, because the four light emitting diodes 58 are electrically connected with each other in series, the operating voltage of the light emitting diode package structure 50 is the summation of the operating voltage of the four light emitting diodes 58. General speaking, the operating voltage of one light emitting diode is about 3.3 volts, so four light emitting diodes connected in series require about 12 volts to operate. For a general specification of an automobile system, the operating voltage is 12 volts so that the light emitting diode package structure 50 can be directly applied to the automobile system. Furthermore, the number of the cup-structures 54 and the light emitting diodes 58 of the present invention is not limited to only four, and the operating voltage of the light emitting diodes in series is also not limited to 12 volts. Therefore, the number of the light emitting diodes 58 and the disposition of the conductive patterns 56 can be modified according to the driving voltage. The present invention can be applied to a high voltage, such as the household voltage (110 volts) or the industrial voltage (220 volts). If the light emitting diode package structure in the prior art needs to apply to the automobile system, the light emitting diode package structure in the prior art must have four packaged light emitting diodes. Therefore, the present invention provides the interconnection in the light emitting diode package structure 50 through the conductive patterns 56 and the wires 60, so the problem in the prior art can be improved. In addition, because the cup-structure 54 of this embodiment has inclined sidewalls, the light emitted from the light emitting diode can be reflected upward so as to increase the light utility of light emitting diode 58. And, because the distance between the edges of the adjacent cup-structures 54 is substantially less than 10 μm, the light emitted from the adjacent light emitting diodes 58 can have light-mixing effect. The light pattern of the light emitting diode package structure 50 can be the same as the light pattern of one light emitting diode.

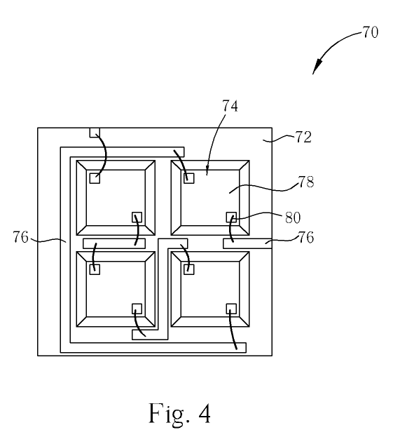

Please refer to FIG. 4. FIG. 4 is a top view illustrating a light emitting diode package structure according to another preferred embodiment of the present invention. For convenience, like structure will not be detailed redundantly. As shown in FIG. 4, the light emitting diode package structure 70 of this embodiment includes a silicon substrate 72, four cup-structures 74, a plurality of conductive patterns 76, four light emitting diodes 78 respectively disposed with one in each cup-structure 74 and a plurality of wires 80. The differences with the above-mentioned embodiment are the conductive patterns of this embodiment disposed on the silicon substrate 72 between the cup-structures 74 and the wires 80 being in substantially the same direction. The wires 80 in the same direction help to reduce the time of bonding wires so as to speed the manufacturing time.

In summary, the present invention provides a light emitting diode package structure having cup-structures to increase light condensation and provides a light emitting diode package structure having cup-structures with high density to reduce light-mixing distance. The present invention also uses a silicon substrate having a conductive layer to make the interconnection in the light emitting diode package structure so as to enable the light emitting diodes to connect with each other in the light emitting diode package structure. The present invention provides a light emitting diode package structure having high operating voltage, light pattern similar to one light emitting diode and small package size.

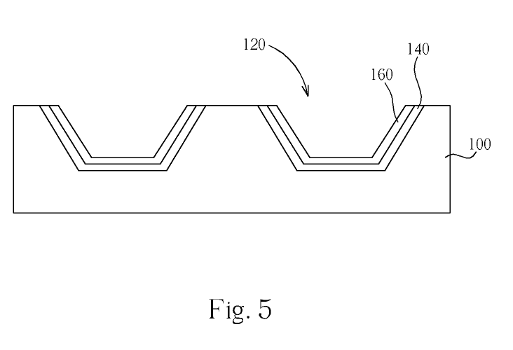

Please refer to FIG. 5 to FIG. 7. FIG. 5 to FIG. 7 are schematic diagrams illustrating a method of making a light emitting diode package structure having a silicon substrate according to an embodiment of the present invention. As shown in FIG. 5, first, a silicon substrate 100 having a plurality of cup-structures 120 thereon is provided. Then, a reflective layer 140 is formed on the silicon substrate 100 in each cup-structure 120, and a transparent insulating layer 160 is formed on the reflective layer 140. The cup-structures 120 can be formed by using a reactive ion etching (RIE) process, a Bosch process or a wet etching process using potassium hydroxide (KOH), tetramethylammonium hydroxide (TMAH) or ethylenediamine-pyrocatechol-water (EDP) as an etching solution. The Bosch process, also known as pulsed or time-multiplexed etching, alternates repeatedly between standard isotropic plasma etch and deposition of a chemically inert passivation layer to achieve nearly vertical structures. The reflective layer 140 and the transparent insulating layer 160 can be formed by sputtering, evaporation or chemical deposition.

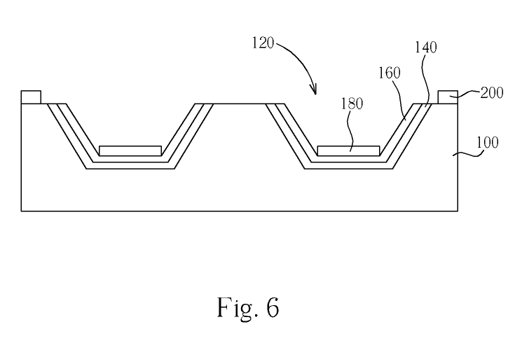

Next, as shown in FIG. 6, a plurality of metal bumps 180 is respectively formed on the transparent insulating layer with one of the plurality in each cup-structure 180. Then, a plurality of conductive patterns 200 is formed on the silicon substrate 100 surrounding the cup-structures 120. The metal bumps 180 and the conductive patterns 200 can be formed by deposition or electroplating combined with a lithographic and etching process or lift off process, and the metal bumps 180 and the conductive patterns 200 can be formed in the same step.

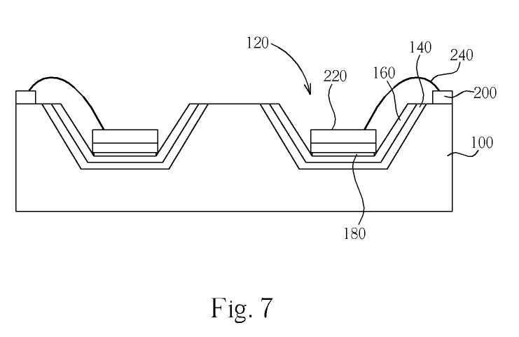

As shown in FIG. 7, one of a plurality of light emitting diodes 220 is respectively bonded to each metal bump 180 in each cup-structure 120. A plurality of wires 240 is used to electrically connect the light emitting diodes 220 and conductive patterns 200, and the light emitting diodes 220 are connected in series. Each light emitting diode 220 bonded to each metal bump 180 in the bottom of each cup-structure 120 is performed by a eutectic bonding method or a die-attached method using glass frit, and connecting the wires 240 to the light emitting diodes 220 and the conductive patterns 200 is performed by a ultrasonic bonding method. The light emitting diode package structure is thus completed.

In summary, the present invention provides a light emitting diode package structure including a plurality of light emitting diodes having interconnection in series and uses a semiconductor process to fabricate a light emitting diode package structure having cup-structures and conductive patterns so as to have small package size and high light utility. The present invention also provides a light emitting diode package structure corresponding to a specific high voltage specification.

Those skilled in the art will readily observe that numerous modifications and alterations of the device and method may be made while retaining the teachings of the invention.

What is claimed is:

1. A light emitting diode package structure, comprising:
a silicon substrate;
a plurality of cup-structures on a top surface of the silicon substrate;
a plurality of conductive patterns disposed on the top surface of the silicon substrate;
one of a plurality of light emitting diodes respectively disposed in each cup-structure;
a plurality of wires electrically connecting the light emitting diodes to the conductive patterns, and the light emitting diodes electrically connected in series through the wires and the conductive patterns.

2. The light emitting diode package structure of claim 1, further comprising a reflective layer and a transparent insulating layer disposed in order on the silicon substrate in the cup-structures.

3. The light emitting diode package structure of claim 2, further comprising one of a plurality of metal bumps respectively disposed on the transparent insulating layer in each cup-structure.

4. The light emitting diode package structure of claim 1, wherein each cup-structure has inclined sidewalls.

5. The light emitting diode package structure of claim 1, wherein a distance between edges of adjacent cup-structures is substantially less than 10 μm.

6. The light emitting diode package structure of claim 1, wherein the conductive patterns are disposed surrounding the cup-structures.

7. The light emitting diode package structure of claim 1, wherein the conductive patterns are disposed on the silicon substrate between the cup-structures.

8. The light emitting diode package structure of claim 7, wherein the wires are disposed at substantially the same direction.

9. A method of fabricating a light emitting diode package structure, comprising:
providing a silicon substrate having a plurality of cup-structures;
forming a plurality of conductive patterns on the silicon substrate;
respectively disposing one of a plurality of light emitting diodes in each cup-structure; and
electrically connecting the light emitting diodes to the conductive patterns through a plurality of wires, and the light emitting diodes electrically connected in series through the wires and the conductive patterns.

10. The method of claim 9, wherein the cup-structures are formed on a top surface of the silicon substrate by an etching process.

11. The method of claim 10, wherein the etching process is a reactive ion etching process, a Bosch process or a wet etching process using KOH, TMAH or EDP as an etching solution.

12. The method of claim 9, further comprising a step of forming a reflective layer and a transparent insulating layer in order on the silicon substrate in the cup-structures before forming the conductive patterns.

13. The method of claim 12, further comprising a step of forming one of plurality of metal bumps respectively on the transparent insulating layer in each cup-structure after forming the reflective layer and the transparent insulating layer.

14. The method of claim 13, wherein each light emitting diode bonded to each metal bump at a bottom of each cup-structure is performed by a eutectic bonding method.

15. The method of claim 13, wherein each light emitting diode bonded to each metal bump at a bottom of each cup-structure is performed by a die-attached method using glass frit.
